(19) United States
(12) Patent Application Publication
(10) Pub. No.: US 2008/0308870 A1
(43) Pub. Date: Dec. 18, 2008

(54) INTEGRATED CIRCUIT WITH A SPLIT FUNCTION GATE

(75) Inventors: Juergen Faul, Radebeul (DE); Stefan Slesazeck, Dresden (DE); Martin Popp, Dresden (DE); Rolf Weis, Dresden (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/763,796

(22) Filed: Jun. 15, 2007

(51) Int. Cl. H01L 29/76

(52) U.S. Cl. 257/368; 257/E29.226

(57) ABSTRACT

An integrated circuit is disclosed. One embodiment provides a field-effect transistor including a gate electrode, a channel region and a first source/drain region. The gate electrode may include a main section determining a first flat band voltage between the gate electrode and the channel region and a first lateral section that is in contact with the main section and that determines a second flat band voltage between the gate electrode and the first source/drain region. The first and second flat band voltages differ by at least 0.1 eV.

### BACKGROUND

Scaling down MOSFETs to channel lengths below 90 nm, minimization of off-state leakage current becomes an important issue for low-power applications. For example, MOSFETs may be used to isolate temporarily such network nodes for which nearly no loss of charge is admissible during the transistor off-state. Such applications may be, for example, the access transistors of some types of memory cells, for example DRAM memory cells, select transistors of sensor arrays or transistors in sample/hold circuits, for example, in analog/digital converters.

During the transistor off-state, a leakage current from the isolated network node should be avoided or minimized. One of the leakage mechanisms in such applications is the gate induced drain leakage (GIDL) current which results from strong electrical fields in the region of the pn-junction of that source/drain region that is orientated to the critical network node. A large drain-to-gate bias may bend the energy band for valence-band electrons near the interface between the semiconductor substrate and the gate dielectric to such degree that the valence-band electrons may tunnel into the conduction band.

GIDL current may be reduced by providing a lightly doped impurity region between the source/drain region orientated to the critical network node and the channel region or by providing suitable insulator structures between the gate electrode and the pn-junction.

In 3D-FETs with the gate electrode buried in a semiconductor substrate between the two source/drain regions, a thick insulating structure between the gate electrodes and the respective source/drain region may reduce the cross-section of the gate electrode between the two source/drain regions such that the resistance of the gate electrode increases.

A need exists for an integrated circuit including field effect transistors with a small gate induced drain leakage current and thin insulator structures between the gate electrode and the source/drain regions.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1A illustrates a schematic cross-sectional view of a planar n-MOSFET with an asymmetric gate electrode according to one embodiment.

FIG. 1B illustrates a schematic cross-sectional view of a planar p-MOSFET with an asymmetric gate electrode according to a further embodiment.

FIG. 1C illustrates a schematic cross-sectional view of a planar n-MOSFET with a symmetric gate electrode according to a further embodiment.

FIG. 1D illustrates a schematic cross-sectional view of a planar p-MOSFET with a symmetric gate electrode according to another embodiment.

FIG. 2 illustrates a schematic cross-sectional view of a vertical n-MOSFET with a symmetric gate electrode according to a further embodiment.

FIG. 3 illustrates a diagram illustrating the principles of a split work function gate.

FIG. 4A illustrates a schematic cross-sectional view of a conventional 3D-n-MOSFET.

FIG. 4B illustrates a schematic cross-sectional view of a 3D-n-MOSFET with a split work function gate based on two gate electrode sections of materials of differing work function according to a further embodiment.

FIG. 4C illustrates a schematic cross-sectional view of a 3D-n-MOSFET with a split work function gate based on biased insulator structures according to another embodiment.

FIG. 4D illustrates a schematic cross-sectional view of a 3D-n-MOSFET with a split work function gate based on three gate electrode sections of at least two materials of differing work function according to another embodiment.

FIG. 5A to 5C illustrate energy band diagrams illustrating the principles of a split work function gate.

FIG. 6 illustrates a schematic cross-sectional view of a memory cell including a 3D-n-MOSFET with split work function gate according to a further embodiment.

FIG. 7 illustrates a simplified perspective view of a FinFET-like n-MOSFET with a symmetric split work function gate according to a further embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

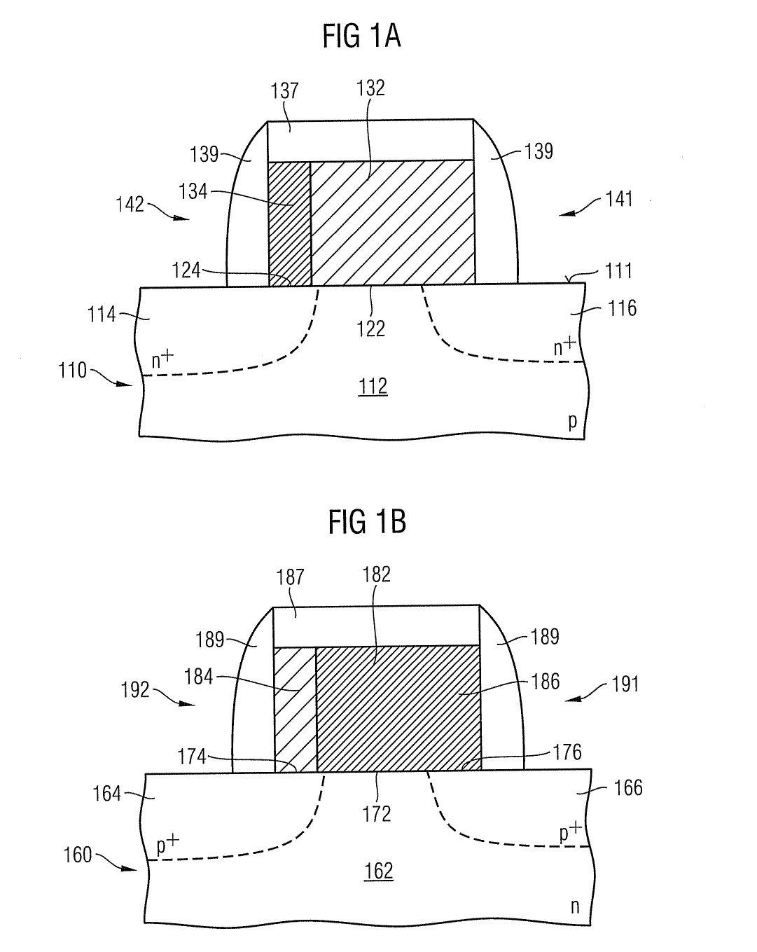

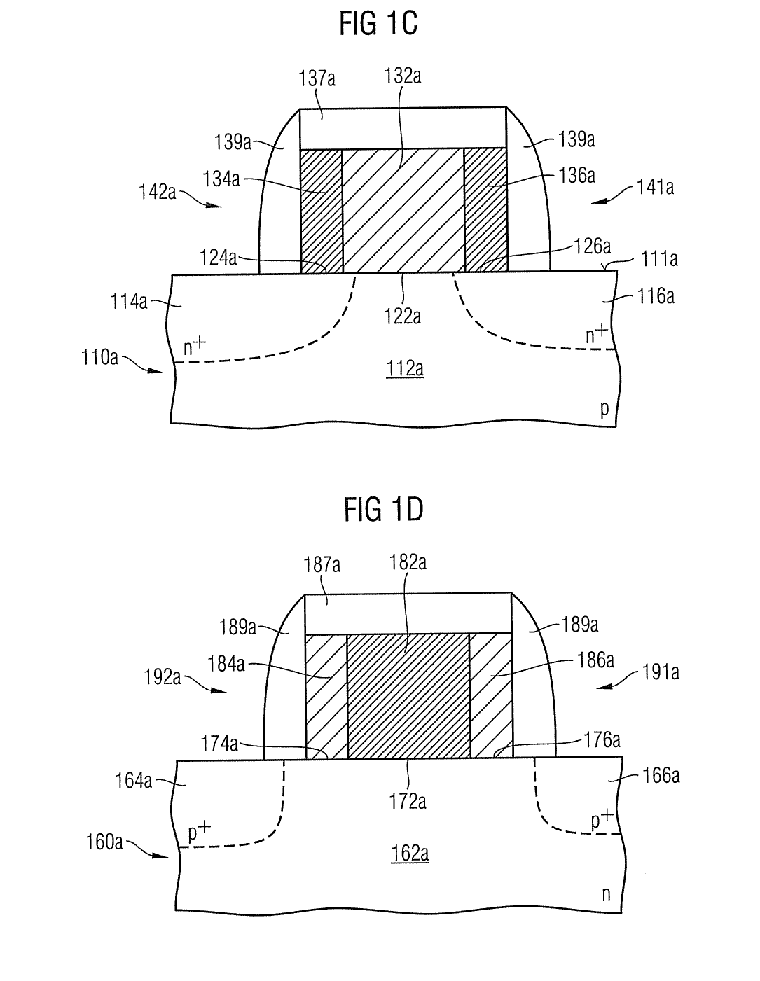

FIG. 1A illustrates an asymmetric planar n-MOSFET 141 which may be part of an integrated circuit that is or includes, for example, a DRAM, a sensor cell or a sample/hold circuit. The n-MOSFET 141 includes a first source/drain region 114 and a second source/drain region 116. The source/drain regions 114, 116 may be heavily n-doped impurity regions within a p-doped section of a semiconductor substrate 110. The substrate 110 may be, by way of example, a preprocessed single crystalline silicon wafer or a silicon-on-insulator wafer and may include further doped and undoped sections, epitaxial semiconductor layers supported by a base conductor or a base insulator as well as other semiconductor and insulator structures that have previously been fabricated.

The first source/drain region 114 and the second source/drain region 116 face each other at a p-conductive channel region 112 that connects the two source/drain regions 114, 116 in the substrate 110. A gate electrode 142 is arranged above the channel region 112 on the substrate surface 111 of the substrate 110. The gate electrode 142 includes a conductive lateral section 134 and a conductive main section 132. The main section 132 faces the channel region 112 at a gate dielectric 122. The main section 132, the gate dielectric 122 and the channel region 112 form a first MOS device (channel device). A MOS device may be characterized by its flat band voltage, i.e. that voltage which must be applied between its electrodes to compensate a charge accumulation resulting from, for example, different work functions of its electrodes. By applying the flat band voltage, the valence and conductivity bands in the semiconductor portion of an MOS device become flat. The flat band voltage depends substantially on material parameters. The channel device may have a first flat band voltage.

The lateral section 134 is in contact with the main section 132 along an interface. The lateral section 134, a first insulator structure 124 separating the lateral section 134 and the substrate 110, and the first source/drain region 114 form a further MOS device (diffusion device), that may be characterized by a second flat band voltage that differs from the first flat band voltage of the channel device by at least 0.1 eV. Depending on the type of the FET (n-channel or p-channel), the first and second flat band voltages are assigned to the main and first lateral section such that an electrical field strength between the first source/drain region and the channel region is reduced in an off-state of the field-effect transistor. For example, in case of the n-MOSFET 141, a material forming the main section may have a work function versus vacuum that is at least 0.1 eV higher than that of a material forming the first lateral section. According to one or more embodiments, the difference in flat band voltage may result from charges trapped in the respective insulator structures or from dipoles aligning in a polar insulator section of the insulator structures when the gate electrode is biased.

According to the illustrated embodiment, the main section 132 overlaps the first source/drain region 114 and faces an inner section of the first source/drain region 114 at a section of the gate dielectric 122. The first insulator structure 124 separates the first lateral section 134 and an outer section of the first source/drain region 114. According to another embodiment, the main section 132 may overlap the first source/drain region 114 and may face the first source/drain region 114 at a section of the first insulator structure 124. According to one or more embodiments, the first source/drain region 114 may overlap the channel region such that the first insulator structure 124 separates the first source/drain region 114 and the first lateral section 134 and a section of the gate dielectric 122 separates the first lateral section 134 and the channel region 112.

A dielectric cap layer 137 may cover the main and the lateral sections 132, 134 and dielectric sidewalls spacers 139 may be formed along the vertical sidewalls of the gate electrode 142. The dielectric cap layer 137 and the sidewall spacers 139 may be made of silicon nitride or silicon oxide, by way of example.

The gate dielectric 122 may be a thermally grown silicon oxide layer. According to other embodiments, the gate dielectric 122 may be a deposited silicon oxide which may be nitrided afterwards or another oxide or silicon oxide of elements of the third or fourth group including oxides of rare earth, for example Al₂O₃, HfO₂, HfSiO₂, CrSiO₂, DySiO₂ or another high-K-material.

The insulator structure 124 may be made of the same materials. By way of example, the gate dielectric 122 and the first insulator structure 124 are made of the same material and may have the same thickness. According to one embodiment, the first insulator structure 124 and the gate dielectric 122 are sections of the same dielectric layer.

As mentioned above, the material of the lateral section 134 may have a lower work function vs. vacuum than that of the main section 132. Due to the lower work function, the electrical field strength near the pn-junction between the first source/drain region 114 and the channel region 112 is reduced compared to a gate electrode having the same structure with the material of the lateral section being replaced by the material of the main section. The first source/drain region 114 may be connected to a critical network node, from which a leakage current to the substrate 110 is to be minimized. The on-state characteristics of the n-MOSFET 141 are dominated by the properties of the main section 132 and are substantially the same as that of an n-MOSFET having the same structure with the material of the lateral section being replaced by the material of the main section.

An asymmetric arrangement as illustrated in FIG. 1A may be adequate to reduce a gate induced drain leakage current in many applications. A symmetric arrangement, as illustrated in FIG. 1C, may simplify a process flow for manufacturing a split work function gate electrode. The embodiment as illustrated in FIG. 1C includes a symmetric planar n-MOSFET 141a with two source/drain regions 114a, 116a that are formed as heavily n⁺-doped impurity regions within a semiconductor substrate 110a. A p-doped channel region 112a is formed by a p-doped section of the substrate 110a and connects the two source/drain regions 114a, 116a. A gate electrode 142a with a main section 132a and two lateral sections 134a, 136a, which face each other at the main section 132a, is arranged above the channel region 112a. A dielectric cap layer 147a covers the main and lateral sections 132a, 134a, 136a and dielectric sidewall spacers 139a extend along the vertical sidewalls of the gate electrode 142a. A gate dielectric 122a separates the main section 132a and the channel region 112a such that the main section 132a and the channel region 112a face each other at the gate dielectric 122a. Two insulator structures 124a, 126a separate the lateral sections 134a, 136a from the substrate 110a. The main section 132a may overlap the source/drain regions 114a, 116a, such that portions of the main section 132a face sections of the source/drain regions 114a, 116a.

According to the illustrated embodiment, the lateral sections 134a, 136a overlap the channel region 112a such that each lateral section 134a, 136a includes a portion that faces a section of the channel region 112a at the gate dielectric 122a. According to another embodiment, the main section 132a may overlap the source/drain regions 114a, 116a such that portions of the main section 132a are directly opposite of sections of the source/drain regions 114a, 116a at the corresponding insulator structure 124a, 126a. In this case, the metallurgic border, i.e. the interface at which the net impurity concentration changes from n-conductive to p-conductive, is below the respective lateral section 134a, 136a.

The material of the main section 132a may be, for example, heavily p-doped polysilicon with a work function vs. vacuum of about 5.1 eV. The material of the lateral sections 134a, 136a may be a metal or a metal compound or may include at least one metal or metal compound with a work function vs. vacuum of 4.5 eV or less, for example titanium or tantalum nitride. According to another example, the material of the main section 132a is a metal or a metal compound with a work function vs. vacuum of at least about 4.5 eV, for example titanium or tantalum nitride, and the material of the lateral section 134a, 136a is heavily n⁺-doped polysilicon with a work function of 4.1 eV or less, wherein each lateral section 134a, 136a forms an Ohmic contact with the main section 132a along the respective interface.

A method of manufacturing the n-MOSFET 141a may include deposition or growing of the gate dielectric 122a on the substrate surface 111a. The material of the main section 132a may be deposited on the gate dielectric 122a. Via a photolithographic process using a resist mask, the material of the main section 132a may be patterned to form line-shaped or dot-shaped main sections 132a. The main section 132a may be used as an implant mask during an implant to form, for example n-doped impurity regions that form portions of the source/drain regions 114a and 116a. A clean process may follow to remove particles or non-conductive portions, for example oxidized portions of the main section 132a.

One or more conformal layers including the material of the lateral sections 134a, 136a may be deposited. An anisotropic etch may follow to remove horizontal sections of the conformal layers. Further implants may follow that use the main section 132a and the lateral sections 134a, 136a as combined implant mask to form further portions of the source/drain regions 114a, 116a. Asymmetric masks facilitating asymmetric transistor configurations as illustrated in FIG. 1A or FIG. 1B may be formed, for example, using oblique implantation to alter locally the etch resistance of a mask layer. Another approach to form asymmetric transistors includes a further lithography process to create openings in a resist layer, through which portions of the lateral sections 134a, 136a may be removed before performing the anisotropic etch described above.

FIG. 1B and FIG. 1D refer to p-MOSFETs that correspond to the n-MOSFETs of FIGS. 1A and 1C with the reference numbers increased by 50 respectively. The source/drain regions 164, 166, 164a, 166a are p⁺-doped impurity regions. The channel regions 162, 162a are n-doped. The material of the respective main section 182, 182a may have a first work function and that of the lateral section 184 or the lateral sections 184a, 186a may have a second work function that is higher than the first work function. The material of the main section 182, 182a may be, by way of example, n-doped polysilicon with a work function vs. vacuum of about 4.1 eV or less. The material of the lateral section 184 and the lateral sections 184a, 186a may be a metal or metal compound or may include at least one metal or metal compound with a work function of about 4.5 eV or more, by way of example. The difference in work function may be at least about 0.5 eV.

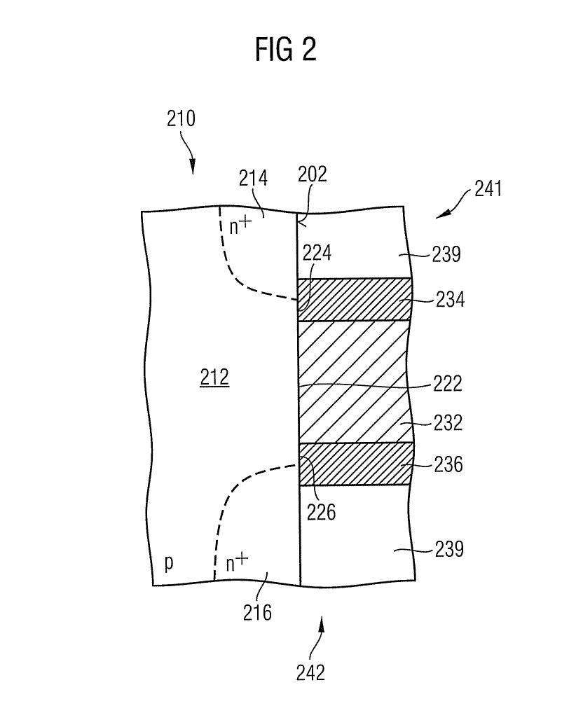

FIG. 2 refers to a vertical n-MOSFET 241. A substrate 210 may be patterned such that a vertical interface 202 is formed, which is orthogonal to a process surface of the substrate 210, for example a pattern surface of a wafer. Within the substrate 210, a first impurity region 214 is formed above a buried second impurity region 216, wherein the second impurity region 216 does not directly adjoin the process surface. The first and the second impurity regions 214, 216 form a first and a second source/drain region. A p-doped section of the substrate 210 forms a channel region 212 that connects the first and the second source/drain region 214, 216 in the substrate 210. Along the vertical interface 202, a first lateral section 236, a main section 232 and a second lateral section 234 of a gate electrode 242 are stacked above each other in this order. At least a center portion of the main section 232 faces the channel region 212 at a gate dielectric 222 that is arranged between them. The first and the second lateral section 234, 236 face the respective source/drain region 214, 216 at a corresponding insulator structure 224, 226 at least in sections. The main section 232, the gate dielectric 222 and the channel region 212 form a channel device as yet discussed with regard to FIG. 1A. The channel device may be characterized or specified by a first flat band voltage. The first and second lateral sections 234, 236, which are in contact with the main section along the interface, the first and second insulator structures 224, 226 and the first and second impurity regions 214, 216 form diffusion devices, wherein each diffusion device may be specified by a second flat band voltage between the gate electrode and the respective source/drain region. The first and second flat band voltage may differ by at least 0.1 eV, for example by at least 0.5 eV, wherein the higher and the lower flat band voltage are assigned to the respective main and lateral section so as to reduce an electrical field strength between the first source/drain region and the channel region in an off-state of the field-effect transistor. The assignment depends on the transistor type.

According to an embodiment related to an n-MOSFET, the difference in flat band voltage results from a difference in work function between two different materials, wherein the material with the higher work function is assigned to the main section and the material with the lower work function is assigned to the lateral sections.

According to an embodiment related to a p-MOSFET, the difference in flat band voltage results from a difference in work function between two different materials, wherein the material with the lower work function is assigned to the main section and the material with the higher work function is assigned to the lateral sections.

According to the embodiment illustrated in FIG. 2, the material of the lateral sections 234, 236 may have a lower work function than that of the main section 232, such that an electrical field strength in the pn-junction may be reduced. Further dielectric structures 239 may be provided below the lower lateral section 236 and above the upper lateral section 234 to insulate the gate electrode structure 242 towards neighboring conductive structures.

The metallurgic interfaces between the n-doped source/drain regions 214, 216 and the p-conductive channel region 212 may be aligned to the interfaces between the main section 232 and the respective lateral section 236, 234 or may hit the interface 202 in the area of the main section 232 or in the area of the corresponding lateral section 234, 236.

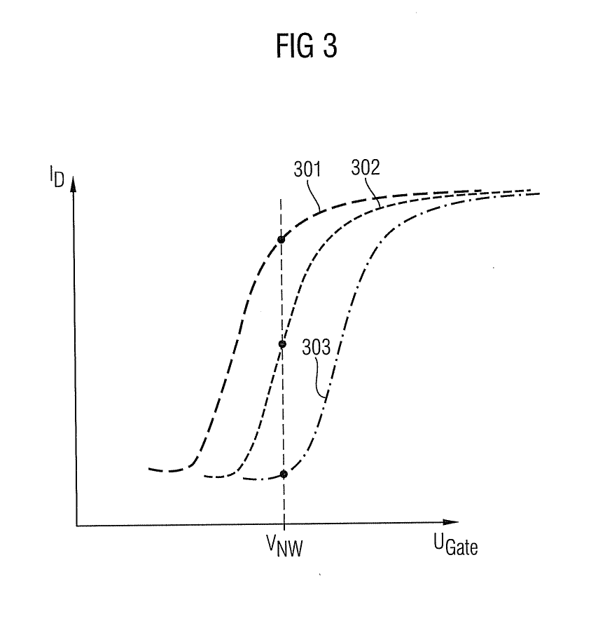

The diagram of FIG. 3 plots the drain current Idrain against the gate voltage Ugate for the conductive state.

The curve 301 refers to an n-MOSFET with an n-doped polysilicon gate electrode without lateral sections and with a work function of about 4.05 eV. The curve 303 refers to a structurally equivalent n-MOSFET with the gate electrode made of p-doped polysilicon with a work function of about 5.1 eV. The curve 302 refers to a structurally equivalent n-MOSFET with a gate electrode made of a material having a work function of about 4.45 eV.

With regard to the curves 301 to 303, the threshold voltage at which, in the on-state, the drain current IDrain increases significantly with increasing gate voltage Ugate, depends on the work function of the gate electrode. A low work function of the gate electrode corresponds to a low threshold voltage. In the off-state, the gate induced drain leakage current increases with increasing drain-to-gate voltage Udg. With increasing drain-to-gate voltage Udg, a parasitic transistor device controlled by the drain-to-gate voltage Udg turns gradually “on”, wherein a low GIDL current corresponds to a low work function.

A combined device with a low work function towards the source/drain region and a high work function towards the channel region, for example, with a p-doped main section having a work function of about 5.1 eV and a lateral section having a work function of about 4.45 eV, may have, in the off-state, a GIDL current equivalent to a 4.45 eV device, while the drain current in the on-state is determined by the work function towards the channel region and follows curve 303.

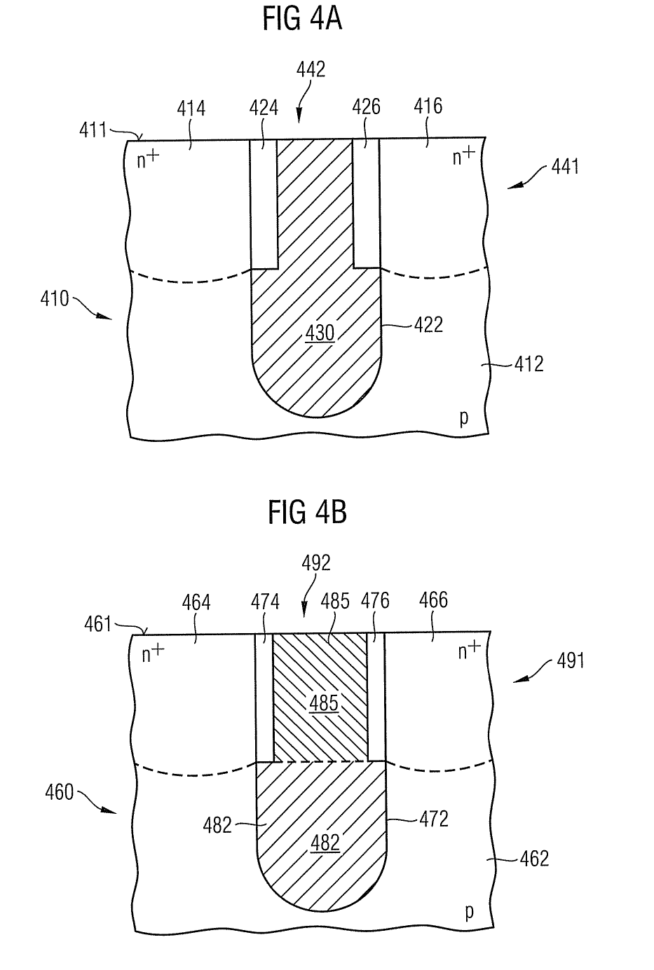

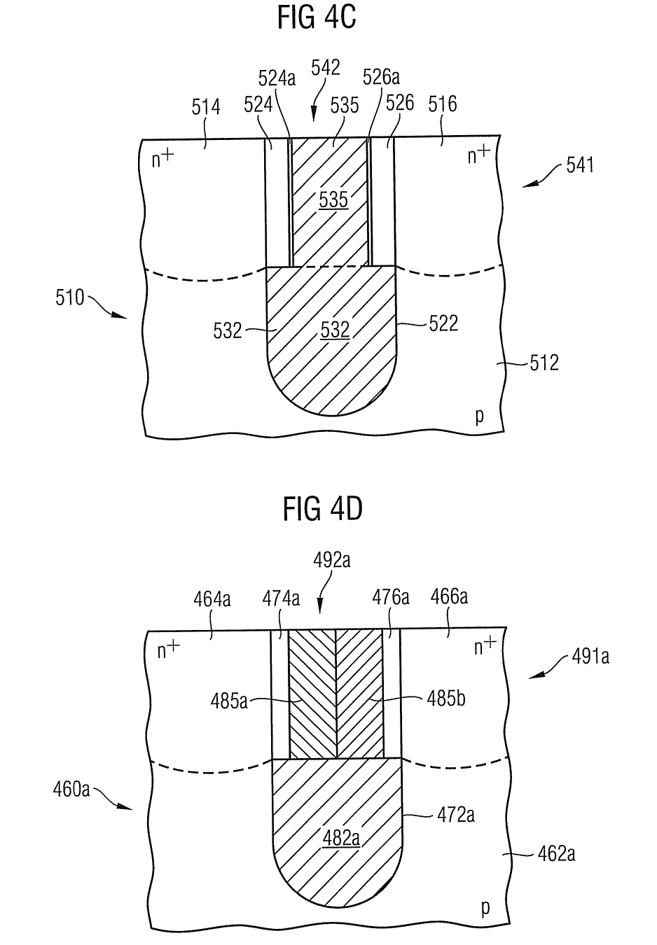

FIG. 4A to FIG. 4C refer to 3D-n-MOSFETs that includes a buried gate electrode section that separates the two source/drain regions. The gate electrode may have a lower edge below at least one of the lower edges of the source/drain regions. The source/drain regions face each other at the gate electrode. Various modifications of 3D-FETs exist, for example, “corner devices” with sections of the gate electrode extending on at least two sides of a substrate lamella that includes at least a portion of the channel region, wherein the electrical field strength in at least one edge region of the lamella is increased due to superposition from different sides. FinFET-like corner devices may include a lamella that is thinned to a fully depleted fin. Embodiments of the invention apply to all of these variants in an equivalent way. As emphasis is placed upon illustrating the principles, the cross-sectional views of FIG. 4A to 4C and those of the following figures refer to a simple U-groove device as an exemplary embodiment for the various types of 3D-MOSFETs. Though only n-MOSFETs are illustrated, the same principles may be applied to p-MOSFETs as discussed with reference to FIG. 1A to 1D.

FIG. 4A is a simplified cross-sectional view of an U-groove n-MOSFET 441 as a simple embodiment of a 3D-n-MOSFET. A first and a second source/drain region 414, 416 are formed as n-doped impurity regions in an upper section of a substrate 410 and adjoin to a substrate surface 411 of the substrate 410. Between the two source/drain regions 414, 416 a gate electrode 430 is buried in the substrate 410, wherein the lower edge of the gate electrode 430 may be below the lower edge of at least one of the source/drain regions 414, 416. Below the two source/drain regions 414, 416, the substrate 410 has a p-conductive channel region 412. A gate dielectric 422 separates the gate electrode 430 and the channel region 412. A first insulator structure 424 separates the gate electrode 430 and the first source/drain region 414 and a second insulator structure 426 separates the gate electrode 430 and the second source/drain region 416.

During the on-state of the n-MOSFET 441, an inversion zone of minority charge carriers forms a conductive channel that extends next to the gate dielectric 422 within the channel region 412 between the lower edge of the first source/drain region 414 and the lower edge of the second source/drain region 416.

The 3D-n-MOSFET 441 may be formed by etching a groove into the semiconductor substrate 410, forming the gate dielectric 422 on the inner sidewalls of the groove, for example through a conformal deposition method like atomic layer deposition or chemical vapor deposition. The material of the main section may be deposited to fill the grooves and then recessed such that the upper edge of the material of the main section falls below the substrate surface. Then the first and second insulator structures 424, 426 may be formed, for example by depositing a further dielectric layer and then patterning the dielectric layer anisotropically. Then the material of the lateral section 485 may be deposited in the upper section of the groove. By asymmetric patterning methods that use, for example, oblique implants to change locally the etch resistance of a suitable mask layer, asymmetric first and second insulator structures 424, 426 or asymmetric lateral sections 485a, 485b as illustrated in FIG. 4D may be formed. According to another embodiment, a further lithography process may be provided to create openings in a resist layer, through which asymmetric insulator structures 424, 426 and/or symmetric or asymmetric first and second lateral sections 485a, 485b as illustrated in FIG. 4D may be formed.

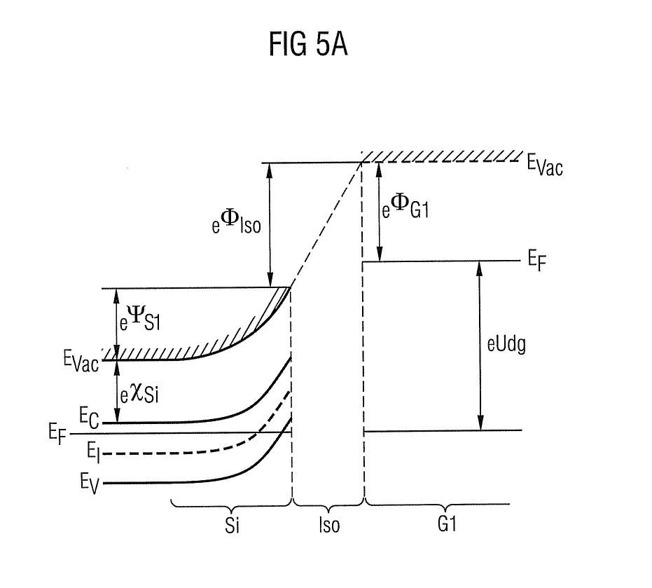

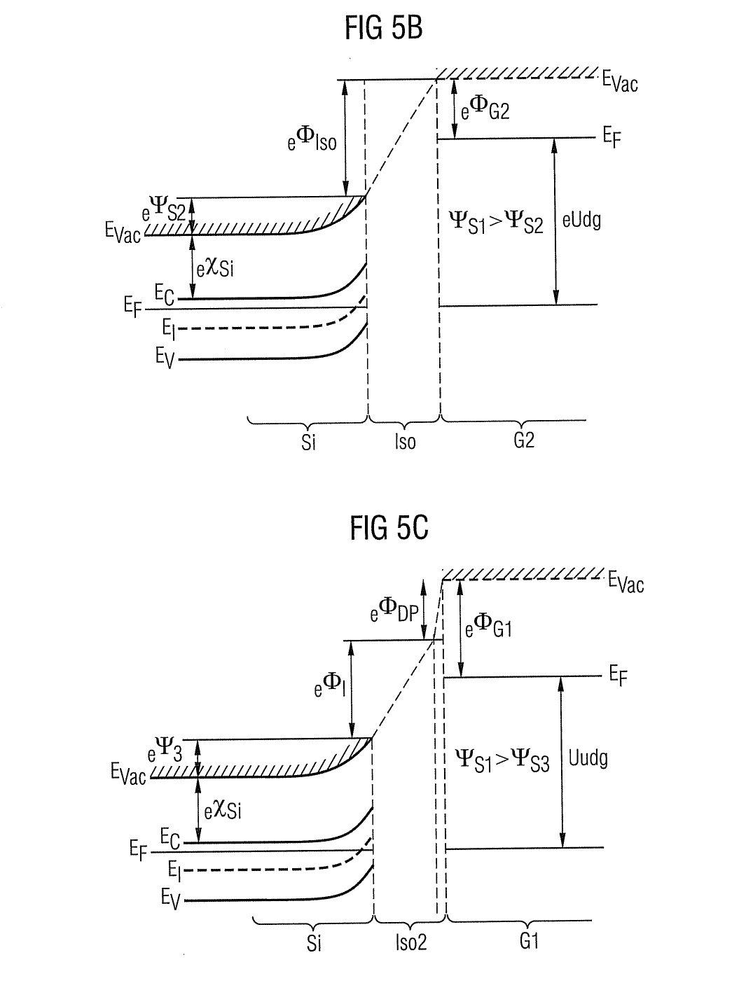

FIG. 5A illustrates the energy band diagram for the diffusion device in the off-state of the n-MOSFET 441. The drain-to-gate voltage Udg, the work function eΦ(G1) of the gate electrode G1, and the electron affinity eX(Si) of the substrate Si determine a potential drop over the insulator U(Iso) and the bending eΨ(S1) of the valence band EV in the substrate Si towards the conduction band EC. In this example, the valence band EV bends up such that the probability of band-to-band tunneling of electrons near the insulator Iso is significantly increased. In other words, during the off-state of the n-MOSFET 441, a high electrical field strength in the area of the pn-junctions between the source/drain regions 414, 416 and the channel region 412 causes a gate induced drain leakage current between the respective source/drain region 414, 416 and the substrate bulk. This leakage current may discharge the respective network node and may lower a signal amplitude derived from a charge stored on the network node. Increasing the gate voltage in order to reduce the drain-to-gate voltage Udg, however, would gradually turn on the n-MOSFET 441. Increasing the thickness of the first and second insulator structures 424, 426 would result in a reduced cross-section of the gate electrode 430 in an upper section orientated to the substrate surface 411 and may increase the electrical resistance between a lower section of the gate electrode that controls the channel on one hand and a gate line or gate terminal that is arranged above the substrate surface 411 on the other hand. The switching time of the n-MOSFET 441 may increase.

FIG. 4B illustrates a simplified cross-sectional view of a 3D-n-MOSFET 491 according to an embodiment of the invention. The n-MOSFET 491 includes a gate electrode 492 that is buried in a substrate 460 between a first source/drain region 464 and a second source/drain region 466, wherein a lower edge of the gate electrode 492 is below a lower edge of at least one of the source/drain regions 464, 466. A gate dielectric 472 separates a main section 482 of the gate electrode 492 and a p-conductive channel region 462 that adjoins the lower edges of the first source/drain region 464 and the second source/drain region 466. A first insulator structure 474 separates a lateral section 485 of the gate electrode 492 and the first source/drain region 464 and a second insulator structure 476 separates the lateral section 485 and the second source/drain region 466. The lateral section 485 is in contact with the main section 482 and is arranged between the main section 482 and a substrate surface 461 of the substrate 460. The lateral section 485 may be connected to a gate terminal or gate line provided above the substrate surface 461. The lateral section 485 may be formed together with the gate terminal or the gate line and/or may result from the same process layer as those.

The material of the main section 482 has a first work function vs. vacuum and the material of the lateral section 485 has a second work function vs. vacuum that may be lower than the first work function. The first and the second work function may differ, by way of example, by at least 0.1 eV, for example by at least 0.25 eV, or, according to another example by at least 0.75 eV. According to the illustrated embodiment, which refers to an n-MOSFET with a p-doped channel region 462, the first work function may be 4.7 to 5.3 eV. The material forming the main section 482 may be heavily doped p-doped polysilicon with a work function of about 5.1 eV. The material forming the lateral section 485 may be a metal or a metal compound, forming an Ohmic contact with the polysilicon of the main section 482, respectively. The lateral section 485 may include a titanium nitride liner with a tungsten fill resulting in a work function of about 4.5 eV. According to one or more embodiments, the lateral section 485 is a tantalum nitride, for example GdTaN or IrTaN with a work function of about 4.2 eV.

FIG. 4D illustrates a simplified cross-sectional view of a further 3D-n-MOSFET 491a according to a further embodiment of the invention. The n-MOSFET 491a includes a gate electrode 492a that is buried in a substrate 460a between a first source/drain region 464a and a second source/drain region 466a, wherein a lower edge of the gate electrode 492a is below a lower edge of at least one of the source/drain regions 464a, 466a. A gate dielectric 472a separates a main section 482a of the gate electrode 492a and a p-conductive channel region 462a that adjoins the lower edges of the first source/drain region 464a and the second source/drain region 466a. A first insulator structure 474a separates a first lateral section 485a of the gate electrode 492a and the first source/drain region 464a and a second insulator structure 476a separates a second lateral section 485b and the second source/drain region 466a. The n-MOSFET 491a differs from the n-MOSFET 491 of FIG. 4B in that it includes two lateral sections 485a and 485b based on different materials with different work functions.

The on-state characteristics of the n-MOSFETs 491, 491a are determined by the properties of the main sections 482, 482a and may be, for example, equivalent to that of the n-MOSFET 441 of FIG. 4A.

FIG. 5B illustrates the energy band diagram of the diffusion device in the off-state of the n-MOSFET 491. Again, the drain-to-gate voltage Udg, the work function eΦ(G2) of the lateral section G2, the work function eΦ(S1) of the substrate determine the potential drop over the insulator eΦ(Iso) and the bending eΨ(S2) of the valence band EV towards the conduction band EC in the substrate Si. As illustrated in FIG. 5A, the reduced work function of the lateral section 485 leads to a reduced over-all potential barrier such that the bending of valence band EV is decreased and the distance to the conduction band EC remains larger than in FIG. 5A such that the probability of band-to-band tunneling of electrons near the insulator I is significantly reduced. In other words, in comparison with the gate electrode 430 of the n-MOSFET 441 in FIG. 4A, the reduced work function of the material of the lateral section 485 results in a reduced electrical field strength in an area of the pn-junctions between the source/drain regions 464, 466 and the channel region 462. Providing insulator structures 474, 476 with the same thickness as the insulator structures 424, 426 of the n-MOSFET 441 of FIG. 4A may result in significantly reduced GIDL current. The thickness of the insulator structures 474, 476 may be reduced as illustrated in FIG. 4B in order to decrease the gate resistance and to enhance the switching characteristics of the n-MOSFET 441.

In the embodiment illustrated in FIG. 4B, the pn-junctions are aligned to the lower edge of the insulator structures 474, 476. According to other embodiments, the pn-junctions may be provided above or below the lower edge of the insulator structures 474, 476. The main section 482 may overlap at least one of the source/drain regions 464, 466 or the lateral section 485 may overlap at least on one side the channel region 462. According to one or more embodiments, the lower edges of the first and the second source/drain regions 464, 466 may be provided at different depths. In asymmetric applications with only one critical network node, one of the insulator structures 474, 476 may be formed thinner than the other or, for example, from the same layer, from which the gate dielectric 472 results.

The lateral section 485 and the main section 482 are in contact with each other and form a low resistance interface, for example an Ohmic contact, wherein the material of the main section 482 is heavily doped silicon and the lateral section 485 includes at least a metal liner forming an interface with the heavily doped silicon. The material of the insulator structures 474, 476 may be or may include silicon oxide, for example a porous low-k material. According to other embodiments, at least one of the insulator structures 474, 476 may be or may include a void.

Though explained in detail for a simple U-groove n-MOSFET, the same principles may apply to corner devices (extended U-groove transistors, EUTs) including a gate electrode 492 with plate-like extensions facing each other at a lamella-like channel section or a thinned fully depleted Fin-like lamella section.

FIG. 4C refers to a 3D-n-MOSFET 541 with the flat band voltage of the diffusion device altered by the electrical field of aligned dipoles or charge carriers. The first source/drain region 514, the second source/drain region 516 and the channel region 512 are arranged with regard to each other as explained with reference to FIG. 4A and FIG. 4B. The main section 532 and the lateral section 535 may be of the same material.

Each insulator structure 524, 526 may include a polar insulator layer 524a, 526a. During the off-state of the transistor, dipoles within the polar insulator layer 524a, 526a align and generate an electrical field reducing the bending of the energy bands in the substrate. According to other embodiments, the insulator structures 524, 526 may be biased by embedded charge carriers which are provided in the insulator structures in course of the manufacturing process and that remain permanently fixed in the insulator structures 524, 526 during the lifetime of the n-MOSFET 541. The charge bias is effective only towards the source/drain regions 514, 516 but not to a significant degree towards the channel region. In other words, the charge bias hardly influences the on-state characteristics but is effective as a local bias of the gate electrode that reduces the effective field strength in the source/drain regions 514, 516. The embedded charge may be nitride particles embedded in silicon oxide and charged during deposition or embedded silicon ions in an alumina liner or other liners of oxides rare earths, in which during deposition silicon ions are embedded along an interface to a silicon containing structure.

The energy band diagram describing the off-state of the diffusion device of n-MOSFET 541 is illustrated in FIG. 5A. The drain-to-gate voltage Udg, the work function eΦ(G1) of the gate electrode G1, the electron affinity eΨ(Si) of the substrate Si and the potential caused by the dipole layer eΦ(DP) determine the voltage drop across the insulator Φ(Iso) and the bending Ψ(S3) of the valence band EV in the substrate Si. The potential Φ(DP) reduces the overall potential height, such that the bending of the valence band EV to the conduction band EC and the probability of band-to-band tunneling of electrons near the insulator Iso is significantly reduced. In other words, due to the dipole layers 524a, 526a the effect of the work function of the lateral section 535 versus the corresponding source/drain region 514, 516 is lower than that of the main section 532 towards the channel region 512. The reduced effective work function leads to the same result as the use of materials with different work functions vs. vacuum as explained in detail with reference to FIG. 4B, whereas the on-state conditions are the same as in the n-MOSFET of FIG. 4A.

The effect of the dipole layer interferes with that of the gate voltage and is equivalent to a work function shift. As a result, the insulator structures 424, 426 may be provided thinner in order to improve the gate resistance. Alternatively, provided in the same thickness, the GIDL current may be reduced. The embodiment of FIG. 4B may be combined with that of FIG. 4C, wherein the insulator structures 474, 476 of the n-MOSFET 491 are biased to further reduce the effective work function of the lateral sections towards the source/drain regions.

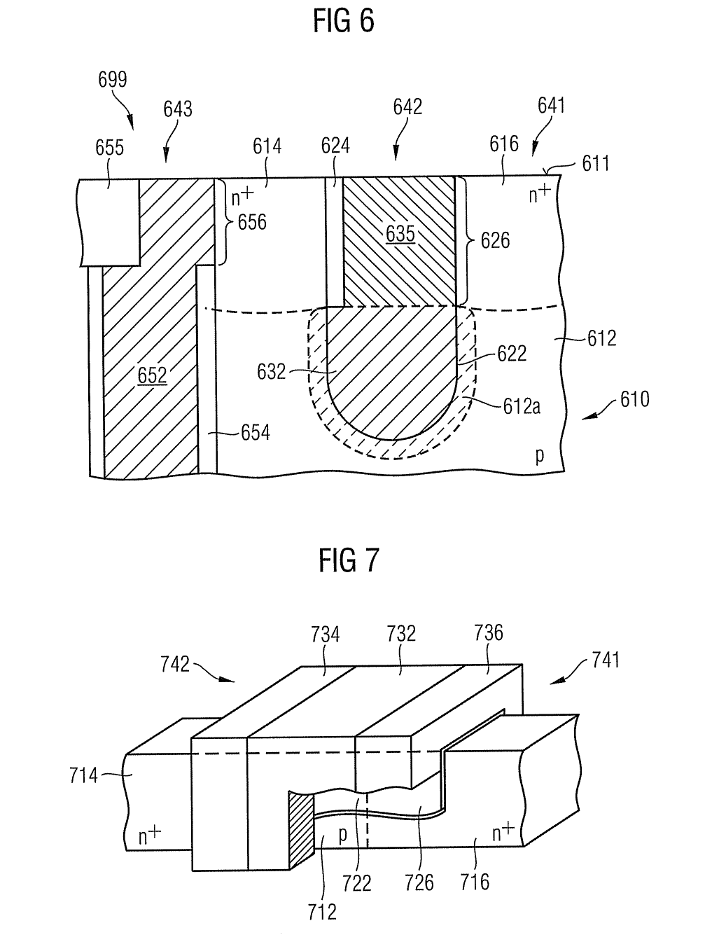

FIG. 6 is a schematic cross-sectional view of a DRAM memory cell including a storage capacitor 643 and an access transistor 642, which is an n-MOSFET. The storage capacitor 643 may be buried in a semiconductor substrate 610 and includes a storage electrode 652 and a counter electrode that is formed as an n-doped impurity region outside the illustrated section of the substrate 610. A collar insulator 654 may insulate an upper section of the storage electrode 652 from the surrounding substrate 610 and a buried conductive interface 656 may electrically connect the storage electrode 652 with a first source/drain region 614 of the access transistor 642. According to other embodiments, the storage capacitor may be buried in an insulating layer disposed over the substrate 610.

The first and the second source/drain regions 614, 616 of the access transistor 642 are n-doped impurity regions within the substrate 610 and are oriented towards a substrate surface 611 of the substrate 610. The lower edge of the first source/drain region 614 may be formed at the same depth as the lower edge of the second source/drain region 616. A gate electrode 642 is buried between the two source/drain regions 614, 616 in the substrate 610, wherein the lower edge of the gate electrode 642 may be below the lower edge of the source/drain regions 614, 616. A gate dielectric 622 separates a main section 632 and a p-doped channel region 612 of the substrate 610, wherein, in the on-state of the access transistor 642, within the channel region 612 a conductive channel of minority charge carriers connects the two source/drain region 614, 616 in an inversion zone along the gate dielectric 622. The channel region 612 may be connected to a supply unit that is configured to supply a constant voltage. A first insulator structure 624 separates a lateral section 635 of the gate electrode 642 and the first source/drain region 614. A second insulator structure 626 separates the lateral section 635 and the second source/drain region 616. The lateral section 635 overlaps the channel region. The substrate 610 may be a single crystalline silicon wafer, which, according to a further example, may be supported by a base insulator. The insulator collars 654 may be a silicon oxide structure and a further insulator structure 655 may be formed to separate neighboring memory cells.

The material of the main section 632 may be heavily p-doped polysilicon. The material of the lateral section 635 may be or may include a metal or a metal compound. The lateral section 635 may comprise, by way of example, a titanium nitride liner and a tungsten fill. The material of the first insulator structure 624 may be a silicon oxide, a porous low-k-fill material or a void that is covered in the following. The second insulator structure 626 may result from the same layer as the gate dielectric 622. The dotted lines refer to plate-like extension sections of the gate electrode that may extend parallel to the illustrated cross-section behind and in front of the illustrated cross-section. The extension sections may enclose a lamella section 612a of the channel region 612 on opposite sides. Along the edges of the lamella section 612a, the electrical fields emanating from the different sections of the gate electrode 642 may superpose in a way such that the on-state characteristics of the n-MOSFET 642 are improved. The lamella section 612a may be thinned to provide a fully depleted semiconductor fin. During the off-state of the n-MOSFET 642, any leakage current from the storage electrode 652 or the source/drain region 614 discharges the storage capacitor 643.

In the off-state, a resulting large drain-to-gate bias may supply sufficient energy to bend up the valence band near the interface between the silicon and the gate dielectric for valence-band-electrons to tunnel into the conduction band. The voltage required to cause this band-to-band tunneling and the resulting leakage current decrease with increasing decoupling between the gate electrode 644 and the first source/drain region 614. A high effective work function of the main portion 632 towards the channel region 612 provides a sufficient coupling of the gate electrode to the channel region and ensures a low drain-to-source resistance RDSon. The low work function of the lateral section 635 towards the first source/drain region 614 reduces the band-to-band tunneling at the pn-junction between the first source/drain region 614 and the channel region 612 and facilitates the use of a comparable thin first insulator structure 624 such that a cross-section of an upper section of the gate electrode 642 may be increased.

The critical network node is typically the node between the storage electrode 652 and the first source/drain region 614. A gate induced leakage current discharges the storage electrode 652 during the off-state of the n-MOSFET 642 and reduces data retention. The GIDL current does not contribute to a data signal of the memory cell. On the other hand, the pn-junction between the second source/drain region 616 and the channel region 612 is less critical, as a GIDL current from the second source/drain region is supplied by the support circuitry and does not contribute to the analysis of the data contents of the memory cell 699. The access transistor 652 may therefore be provided as an asymmetric one as illustrated in FIG. 6 or as a symmetric one as illustrated in FIG. 4B and FIG. 5 in order to reduce process complexity.

FIG. 7 refers to a FinFET-like n-MOSFET 741. At least a channel region 712 of the n-MOSFET 741 is provided within a substrate fin. Two n-doped source/drain regions 714, 716 may face each other in the substrate fin at the p-conductive channel region 712. A gate dielectric 722 extends along the vertical long sides of the channel region and on an upper surface of the channel region 712. A first and a second insulator structure 724, 726 adjoin on both sides of the gate dielectric and may cover portions of the respective source/drain regions 714, 716 along the long sides and on the upper surface. A main section 732 of a gate electrode 742 wraps around the substrate fin and encloses the fin on three sides. Lateral sections 734, 736 of the gate electrode 742 face each other at the main section 732. The material of the lateral section 734, 736 may have a lower work function than that of the main section 732. The first and second insulator structures 724 and the gate dielectric 722 may be sections of the same layer.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit comprising:
a field-effect transistor including a gate electrode, a channel region and a first source/drain region, the gate electrode comprising:
a main section determining a first flat band voltage between the gate electrode and the channel region; and
a first lateral section being in contact with the main section and determining a second flat band voltage between the gate electrode and the first source/drain region; wherein the first and second flat band voltage differ by at least 0.1 eV.

2. The integrated circuit of claim 1, comprising wherein the first and second flat band voltage are assigned to the main and first lateral section such that an electrical field strength between the first source/drain region and the channel region in an off-state of the field-effect transistor is reduced.

3. The integrated circuit of claim 1, comprising wherein the main section has a first work function and the first lateral section has a second work function differing from the first work function by at least 0.1 eV.

4. The integrated circuit of claim 3, comprising wherein the field-effect transistor is an n-MOSFET and the second work function is lower than the first work function.

5. The integrated circuit of claim 3, comprising wherein the field-effect transistor is a p-MOSFET and the second work function is higher than the first work function.

6. The integrated circuit of claim 1, comprising wherein the main section faces at least a section of the channel region at a gate dielectric of the field-effect transistor.

7. The integrated circuit of claim 6, comprising wherein the first lateral section faces at least a section of the first source/drain region at a first insulator structure of the field-effect transistor.

8. The integrated circuit of claim 7, wherein the first insulator structure comprises a polar insulator layer and the difference in flat band voltage results at least in part from a dipole layer induced in the polar insulator layer during the off-state.

9. The integrated circuit of claim 1, comprising wherein the difference in flat band voltage is greater than the difference in work function.

10. The integrated circuit of claim 7, comprising wherein the main section overlaps the first source/drain region.

11. The integrated circuit of claim 7, comprising wherein the first lateral section overlaps the channel region.

12. The integrated circuit of claim 1, comprising wherein a lower edge of the gate electrode is buried below a pattern surface of a substrate that comprises the channel region, the first source/drain region and a second source/drain region of the field-effect transistor, and at least a section of the first source/drain region faces a section of the second source/drain region at the gate electrode.

13. An integrated circuit comprising:
a field-effect transistor including a gate electrode, a channel region and a first source/drain region, the gate electrode comprising:
a main section determining a first flat band voltage between the gate electrode and the channel region;
a first lateral section being in contact with the main section and determining a second flat band voltage between the gate electrode and the first source/drain region; wherein the first and second flat band voltage differ by at least 0.1 eV;
a second lateral section being in contact with the main section, facing the first lateral section at the main section, and determining a third flat band voltage between the second lateral section and a second source/drain region of the field-effect transistor; and
the first and third flat band voltages differing by at least 0.1 eV.

14. The integrated circuit of claim 13, comprising wherein the first and third flat band voltages are assigned to the main and second lateral section such that an electrical field strength between the second source/drain region and the channel region in an off-state of the field-effect transistor is reduced.

15. The integrated circuit of claim 13, comprising wherein the main section has a first work function and the second lateral section has a third work function differing from the first work function by at least 0.1 eV.

16. The integrated circuit of claim 13, comprising wherein the field-effect transistor is an n-MOSFET and the third work function is lower than the first work function.

17. The integrated circuit of claim 13, comprising wherein the field-effect transistor is a p-MOSFET and the third work function is higher than the first work function.

18. The integrated circuit of claim 13, comprising wherein the main section faces at least a section of the channel region at a gate dielectric of the field-effect transistor.

19. The integrated circuit of claim 18, comprising wherein the second lateral section faces at least a section of the second source/drain region at a second insulator structure of the field-effect transistor.

20. The integrated circuit of claim 19, comprising wherein the second insulator structure comprises a polar insulator layer and the difference in flat band voltage results at least in part from dipoles in the polar insulator layer, the dipoles being aligned in the off-state.

21. The integrated circuit of claim 13, comprising wherein the third flat band voltage is equal to the second flat band voltage.

22. The integrated circuit of claim 13, comprising wherein the first lateral section is arranged above the main section and the second lateral section is arranged below the main section.

23. The integrated circuit of claim 19, comprising wherein the respective insulator structure and the gate dielectric are sections of a conformal dielectric liner.

24. The integrated circuit of claim 1, comprising wherein the channel region is p-doped and the first work function is at least 4.6 eV.

25. The integrated circuit of claim 24, comprising wherein a material forming the main section comprises p-doped polysilicon.

26. The integrated circuit of claim 25, wherein a material forming the first lateral section comprises a metal or a metal compound with a work function of 4.5 eV or lower.

27. The integrated circuit of claim 1, further comprising:
a supply unit configured to supply a constant voltage; and
a low resistance connection between the channel region and the a supply unit.

28. The integrated circuit of claim 1, wherein the integrated circuit is or comprises a memory device.

29. An integrated circuit comprising:
a field-effect transistor including a first and a second source/drain region;
a channel region connecting the first and the second source/drain region and a gate electrode, the gate electrode comprising:
first means for determining a first flat band voltage of the gate electrode towards the channel region; and
second means for determining a second flat band voltage of the gate electrode towards the first source/drain region, the first and second flat band voltages differing by at least 0.1 eV.

30. The integrated circuit of claim 29, comprising wherein the first and second flat band voltages are determined such that an electrical field strength between the first source/drain region and the channel region is reduced in an off-state of the field-effect transistor.

31. The integrated circuit of claim 29, further comprising:
third means for determining a third flat band voltage of the gate electrode towards the second source/drain region, the third and the first flat band voltage differing by at least 0.1 eV and the third means adjoining the first means.

32. The integrated circuit of claim 31, comprising wherein the third flat band voltage is equal to the first flat band voltage.

33. An electronic system comprising:
an integrated circuit comprising a field-effect transistor including a first and a second source/drain region, a channel region connecting the first and the second source/drain region and a gate electrode, the gate electrode comprising:
a main section determining a first flat band voltage between the gate electrode and the channel region; and
a first lateral section being in contact with the main section, determining a second flat band voltage between the gate electrode and the first source/drain region, wherein
the first and second flat band voltages differ by at least 0.1 eV.

34. The electronic system of claim 33, comprising wherein the first and second flat band voltages are selected such that an electrical field strength between the first source/drain region and the channel region in an off-state of the field-effect transistor is reduced.

35. The electronic system of claim 33, wherein the electronic system comprises an audio system, a video system, a computer system, a game console, a communication system, a cellular phone, a data storage system, a data storage module, a graphic card or a portable storage device comprising an interface to a computer system, an audio system, a video system, a game console or a data storage system.
